(19) United States
(12) Patent Application Publication
(10) Pub. No.: US 2016/0116775 A1
(43) Pub. Date: Apr. 28, 2016

(54) LIQUID CRYSTAL DISPLAY DEVICE AND MANUFACTURING METHOD THEREOF

(71) Applicant: Samsung Display CO., Ltd., Yongin-Si (KR)

(72) Inventors: Tae Gyun KIM, Seoul (KR); Sae Hee HAN, Seoul (KR); Tae Woon CHA, Seoul (KR)

(21) Appl. No.: 14/876,005

(22) Filed: Oct. 6, 2015

(30) Foreign Application Priority Data
Oct. 28, 2014 (KR) 10-2014-0147447

(51) Int. Cl. G02F 1/1341; H01L 27/12; G02F 1/1368

(52) U.S. Cl. CPC G02F 1/1341; G02F 1/1368; H01L 27/1262

(57) ABSTRACT

A display device according to an exemplary embodiment of the present invention having each pixel that comprises first and second subpixel areas, and an outer partition may be formed along a row direction between a plurality of liquid crystal layers, and the outer partition may separate a first liquid crystal injection hole and a second liquid crystal injection hole of two liquid crystal layers that are adjacent to each other along a column direction, thus liquid crystals are separated rather than being mixed with each other and fill their corresponding microcavities of the first and second subpixels areas.

### CLAIM OF PRIORITY

This application claims the priority to and all the benefits accruing under 35 U.S.C. §119 of Korean Patent Application No. 10-2014-0147447 filed in the Korean Intellectual Property Office (“KIPO”) on Oct. 28, 2014, the entire contents of which are incorporated herein by reference.

### BACKGROUND OF THE INVENTION

1. Field of the Invention

The present invention relates to a liquid crystal display and a manufacturing method thereof.

2. Description of the Related Art

The liquid crystal display, which is one of the most common types of flat panel displays currently in use, includes two sheets of display panels with field generating electrodes such as a pixel electrode, a common electrode, and the like, and a liquid crystal layer interposed therebetween. The liquid crystal display generates an electric field in the liquid crystal layer by applying a voltage to the field generating electrodes to determine an alignment of liquid crystal molecules of the liquid crystal layer through the generated electric field and control polarization of incident light, thereby displaying images.

Two sheets of display panels configuring the liquid crystal display may include a thin film transistor array panel and an opposing display panel. In the thin film transistor array panel, a gate line transferring a gate signal and a data line transferring a data signal are formed to cross each other, and a thin film transistor connected with the gate line and the data line, a pixel electrode connected with the thin film transistor, and the like may be formed. In the opposing display panel, a light blocking member, a color filter, a common electrode, and the like may be formed. In some cases, the light blocking member, the color filter, and the common electrode may be formed on the thin film transistor array panel.

However, in a liquid crystal display in the related art, two sheets of substrates are necessarily used, respective constituent elements are formed on the two sheets of substrates, and as a result, there are problems in that the display device is heavy and thick, is expensive, and has a long processing time.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a display device using one substrate to reduce weight, thickness, manufacturing cost, and processing time, and a method for manufacturing the same.

In addition, different liquid crystals are injected to respective subareas of one pixel of the display device, and the respective subareas of the pixel to which the liquid crystals are injected are symmetrically aligned to thereby prevent a spot from being viewed.

A display device according to an exemplary embodiment of the present invention includes: a substrate; a thin film transistor provided on the substrate; a pixel electrode connected with one terminal of the thin film transistor; a roof layer provided facing the pixel electrode; a liquid crystal layer formed between the pixel electrode and the roof layer and including a first liquid crystal layer having a first liquid crystal injection hole and to which a first liquid crystal molecule is injected and a second liquid crystal layer having a second liquid crystal injection hole and to which a second liquid crystal molecule is injected; an H-shaped inner partition separating the first liquid crystal layer and the second liquid crystal layer; and an outer partition formed in a liquid injection hole forming area of the substrate, wherein the liquid crystal layer may be arranged in plural in a matrix format in the substrate, the outer partition may be formed along a row direction between the plurality of liquid crystal layers, and the outer partition may separate a first liquid crystal injection hole and a second liquid crystal injection hole of two liquid crystal layers that are adjacent to each other along a column direction.

The first liquid crystal layer and the second crystal layer may form one pixel corresponding to one pixel electrode and display different grays, a first valley and a second valley may be formed along a row direction of a plurality of pixels of the display device, and, with respect to two pixels facing each other, interposing the first valley therebetween, a first area of a liquid crystal layer of one pixel may face a second area of a liquid crystal layer of the other pixel.

Areas alternately formed and alternately partitioned in a row direction along the plurality of liquid crystal layers of the outer partition may respectively include only first liquid crystal injection holes or only second liquid crystal injection holes of two pixels adjacent along a row direction, and the first liquid crystal injection hole and the second liquid crystal injection hole may not exist together in each area partitioned by the outer partition.

Only a first area or a second area may exist in a row direction of the plurality of liquid crystal layers of the display device, and the first area and the second area may be alternately disposed along a column direction of the plurality of liquid crystal layers of the display device.

When an electric field is applied to the liquid crystal layer, a tilt degree of liquid crystal molecules in the first area and a tilt degree of liquid crystal molecules in the second area may be different from each other.

The liquid crystal molecules respectively injected to the first area and the second area may have different dielectric constants.

The pixel electrode may include a first pixel electrode and a second pixel electrode respectively located in the first area and the second area, and the first pixel electrode and the second pixel electrode may be connected with each other.

The inner partition and the outer partition may be made of the same material as the roof layer, and the inner partition and the outer partition may be connected with the roof layer.

A first injection hole existing in the first area and a second injection hole existing in the second area of the liquid crystal layer may be disposed opposite to each other with reference to an imaginary line that crosses the center of the liquid crystal layer.

An area of the outer partition, repeated alternately, may be formed in the shape of a quadrangle of which one side is removed.

An area of the outer partition, repeated alternately, may be formed in the shape of a triangle of which one side is removed.

A method for manufacturing a display device according to an exemplary embodiment of the present invention includes: forming a thin film transistor on a substrate; forming a pixel electrode connected with one terminal of the thin film transistor; patterning a sacrificial layer on the pixel electrode to form grooves in the sacrificial layer; forming an outer partition by coating a roof layer on the sacrificial layer and patterning the roof layer; forming a first microcavity where the first liquid crystal injection hole is formed and a second microcavity where the second liquid crystal injection hole is formed by removing the sacrificial layer; and injecting a first liquid crystal material to the first microcavity and injecting a second liquid crystal material to the second microcavity, wherein when coating the roof layer on the sacrificial layer and forming the outer partition, the partition may be formed along a row direction between a plurality of pixels formed on a substrate, and the outer partition may separate a first liquid crystal injection hole and a second liquid crystal injection hole of two liquid crystal layers that are adjacent to each other in a column direction.

When coating the roof layer on the sacrificial layer and forming the outer partition, an inner partition may be formed while the roof layer is filled in the grooves formed by patterning the sacrificial layer.

A first area and a second area of the liquid crystal layer may form one pixel corresponding to one pixel electrode, the outer wall may be alternately formed in a row direction along a plurality of liquid crystal layers, each of areas alternately partitioned by the outer partition may include only first liquid crystal injection holes or only second liquid crystal injection holes of two pixels adjacent to each other in a row direction, and the liquid crystal injection hole and the second liquid crystal injection hole do not exist together in each area partition by the outer partition.

The inner partition and the outer partition may be made of the same material as the roof layer, and when the roof layer is coated and patterned, the inner partition and the outer partition may be simultaneously formed such that the roof layer, the inner partition, and the outer partition are connected all in one step.

A tilt degree of a liquid crystal molecule included in the first liquid crystal material in the first area and a tilt degree of a liquid crystal molecule included in the second liquid crystal material in the second area may be different from each other.

The liquid crystal molecules respectively injected to the first area and the second area may have different dielectric constants.

A plurality of pixels arranged in a matrix format may be formed on a substrate of the display device, only the first area or only the second area may exist along a row direction of the plurality of pixels, and the first area and the second area may be alternately arranged along a column direction of the plurality of pixels of the display device.

An area of the outer partition, repeated alternately, may be formed in the shape of a quadrangle of which one side is removed.

An area of the outer partition, repeated alternately, may be formed in the shape of a triangle of which one side is removed.

As described, according to the exemplary embodiment of the present invention, a partition is formed in the pixel area of the display device and different types of liquid crystal materials are injected to the respective areas partitioned by the partition to thereby improve visibility.

In addition, a partition is formed between adjacent pixels for alternate injection of different types of liquid crystal materials, thereby preventing generation of a spot.

### BRIEF DESCRIPTION OF THE DRAWINGS

FIG. 1 is a top plan view of a display device according to an exemplary embodiment of the present invention.

FIG. 2 is a top plan view of one pixel of the display device according to the exemplary embodiment of the present invention.

FIG. 3 is a cross-sectional view of FIG. 2, taken along the line III-III.

FIG. 4 is a cross-sectional view of FIG. 2, taken along the line IV-IV.

FIG. 5 to FIG. 8 illustrate a liquid crystal injection process of the display device according to the exemplary embodiment of the present invention.

FIG. 9 and FIG. 10 illustrate a liquid crystal injection process of a display device according to a comparative embodiment of the present invention.

FIG. 11 shows a display device according to another exemplary embodiment of the present invention.

FIG. 12 to FIG. 20 are cross-sectional views of the display device according to processes for the exemplary embodiment of the present invention with reference to a cross-section of XII-XII of FIG. 1.

FIG. 21 illustrates a process for injecting different liquid crystals.

FIG. 22 and FIG. 23 illustrate that a tilt degree of liquid crystal molecules is changed when different liquid crystal molecules are applied to each pixel area.

### DETAILED DESCRIPTION OF INVENTION

The present invention will be described in details hereinafter with reference to the accompanying drawings, in which exemplary embodiments of the invention are shown. As those skilled in the art would realize, the described embodiments may be modified in various different ways without departing from the teaching or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a display device according to an exemplary embodiment of the present invention will be described with reference to the accompanying drawings.

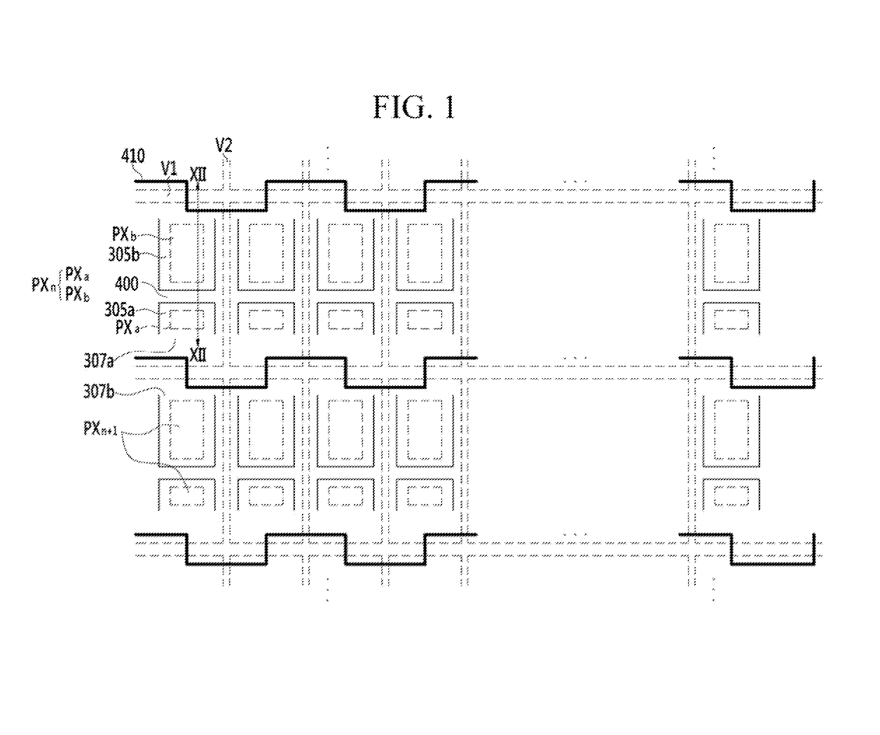

FIG. 1 is a top plan view of a display device according to an exemplary embodiment of the present invention, and only a part of constituent elements is illustrated for convenience of description.

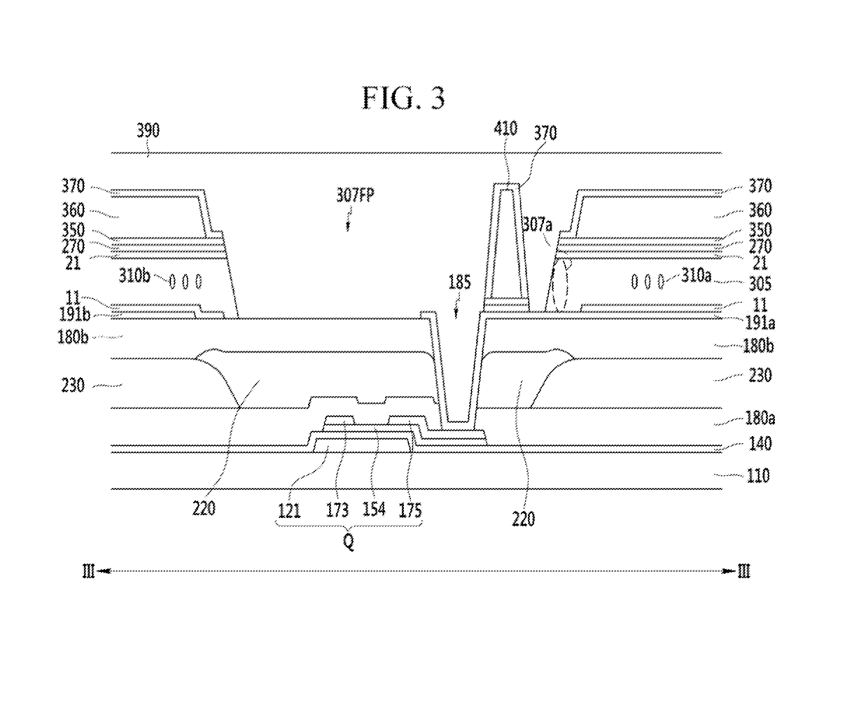

The display device according to the exemplary embodiment of the present invention includes a substrate 110 (see FIG. 3) made of a material such as glass or plastic.

The substrate 110 includes a plurality of pixel areas PX. The plurality of pixel areas PX are arranged in a matrix format including a plurality of pixel rows and a plurality of pixel columns. Each pixel area PX may include a first subpixel area PXa and a second subpixel area PXb. The first subpixel area PXa and the second subpixel area PXb may be vertically disposed. The first subpixel area PXa and the second subpixel area PXb may have a same size, or as shown in FIG. 1, the size of the first subpixel area PXa may be smaller than the size of the second subpixel area PXb.

In one pixel PX, the first subpixel area PXa and the second subpixel area PXb are separated from each other by an inner partition 400.

A first valley V1 is provided between neighboring subpixel areas PX in a pixel row direction, and a second valley V2 is provided between the plurality of pixel columns.

A roof layer (not shown) is formed in a pixel row direction. Each roof layer is formed at a distance from the substrate 110 between neighboring second valleys V2 such that a microcavity (305a, 305b) is formed. In addition, each roof layer is formed to be attached to the substrate 110 in the second valley V2 and thus covers lateral side surfaces of the microcavity 305.

In this case, an injection hole (307a, 307b) is formed in the first valley V1 such that constituent elements located below the roof layer are exposed to the outside when the roof layer is removed.

In this case, an injection hole formed in the first subpixel area is called a first injection hole 307a and an injection hole formed in the second subpixel area is called a second injection hole 307b.

In one pixel, the injection hole is formed in each of the first subpixel area and the second subpixel area. As shown in FIG. 1, when the first injection hole 307a is formed in the right side of the first subpixel area, the second injection hole 307b is formed in the left side of the second subpixel area, and vice versa. That is, the location of the first injection hole 307a and the location of the second injection hole 307b are opposite to each other with reference to a vertical central axis of one pixel.

An outer partition 410 is formed along a pixel row direction in the first valley V1. The outer partition 410 is, as shown in FIG. 1, formed in the shape of a plurality of teeth and thus concave portions and convex portions are repeated along the pixel row direction.

Referring to FIG. 1, the outer partition 410 is formed alternately adjacent to a first microcavity 305a and a second microcavity 305b of each of two neighboring pixels, interposing the first valley V1 in a column direction. Thus, a vertically directed partition is formed between two pixels adjacent to each other in the column direction.

That is, with reference to the same row, when a horizontally directed partition is formed adjacent to a first subpixel area PXa of a pixel located in an N-th column, another horizontally directed partition is formed adjacent to a second subpixel area PXb of a pixel located in an (N+1)-th column and a vertically directed partition is formed between the pixel in the N-th column and the pixel in the (N+1)-th column; the vertically directed partition connects the two horizontally directed partitions.

One tooth partitioned by the vertically directed partition is shared by two pixels that are adjacent to each other in a row direction, interposing the second valley V2 therebetween. Referring to FIG. 1, each tooth exposes half of each of first subpixel areas of the two pixels adjacent to each other in the row direction. Thus, a first injection hole 307a of one pixel and a first injection hole 307a of the adjacent pixel are formed in one tooth.

Likewise, the next tooth includes second injection holes 307b of second subpixel areas of the two pixels adjacent to each other in the row direction.

As described, the tooth-shaped outer partition 410 is formed to alternately include first injection holes and second injection holes of adjacent pixels along the first valley V1, and the first injection hole and the second injection hole are not included in the same tooth. Thus, different types of liquid crystal may be injected to a first subpixel area PXa connected with the first injection hole 307a and a second subpixel area PXb connected with the second injection hole 307b.

That is, in the display device according to the exemplary embodiment of the present invention, the first subpixel area PXa and the second subpixel area PXb of one pixel are partitioned by the inner partition 400, and the saw-tooth type outer partition 410 is formed between pixels PXₙ and PXₙ₊₁, neighboring each other in the column direction. The first injection holes 307a and the second injection holes 307b of the pixels adjacent to each other in the column direction are separated from each other by the tooth-type outer partition 410.

Accordingly, different types of liquid crystals are injected to the first subpixel area PXa and the second subpixel area PXb respectively of each pixel in the display device according to the exemplary embodiment of the present invention.

In this case, liquid crystal injected to each area may have a different dielectric constant. Thus, although a structure of the thin film transistor is simplified, visibility can be improved by injection of the different types of liquid crystal to the respect areas.

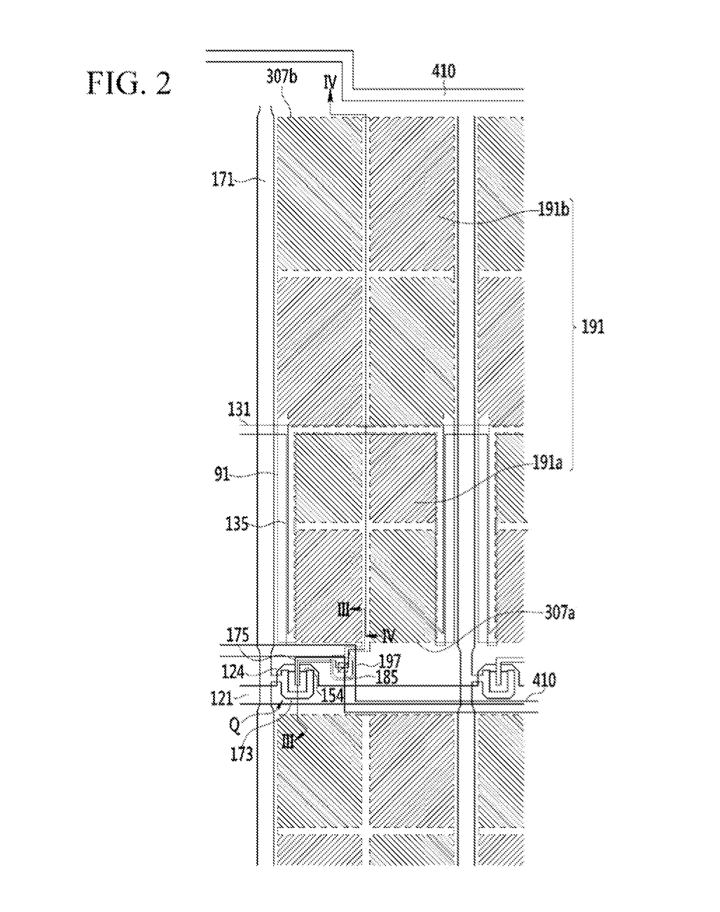

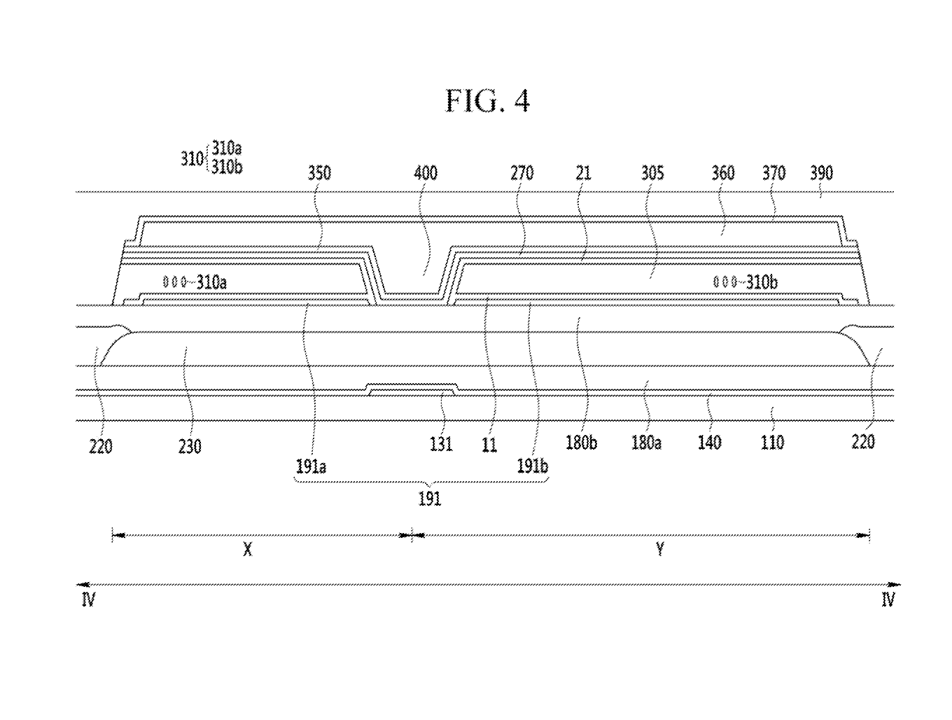

Next, a pixel of a display device according to an exemplary embodiment of the present invention will be described with reference to FIG. 2 to FIG. 4. FIG. 2 is a top plan view of a pixel of a display device according to an exemplary embodiment of the present invention. FIG. 3 is a cross-sectional view of FIG. 2, taken along the line III-III. FIG. 4 is a cross-sectional view of FIG. 2, taken along the line IV-IV.

Referring to FIG. 2 to FIG. 4, a gate line 121 and a storage electrode line 131 are provided on an insulating substrate 110 made of transparent glass or plastic. The gate line 121 includes a gate electrode 124. The storage electrode line 131 substantially extends in a horizontal direction and transmits a predetermined voltage such as a common voltage Vcom. The storage electrode line 131 is substantially parallel with the gate line 121, and includes a pair of storage electrode portions 135 extended in parallel with the gate line 121 to face each other.

A gate insulating layer 140 is formed on the gate line 121 and the storage electrode line 131. A linear semiconductor layer (not shown) provided on a lower part of a data line 171 and a semiconductor layer 154 provided on a lower part of source/drain electrodes 173/175 and a channel of a thin film transistor Q are provided on the gate insulating layer 140.

An ohmic contact may be provided between the linear semiconductor layer and the data line 171 or the semiconductor layer 154 and the source/drain electrodes 173/175, but is omitted in the drawing.

Data conductors 171, 173, and 175 including the data line 171, the source electrode 173 connected with the data line 171, and the drain electrode 175 are formed on the linear semiconductor layer, the semiconductor layer 154, and the gate insulating layer 140.

The gate electrode 124, the source electrode 173, and the drain electrode 175 form the thin film transistor Q together with the semiconductor layer 154, and a channel of the thin film transistor Q is formed in a part of the semiconductor layer 154 between the source electrode 173 and the drain electrode 175.

A first interlayer insulating layer 180a is formed on the data conductors 171, 173, and 175 and an exposed part of the semiconductor layer 154. The first interlayer insulating layer 180a may include an inorganic insulator such as a silicon nitride (SiNₓ) and a silicon oxide (SiOₓ), or an organic insulator. The first interlayer insulating layer 180a planarizes a surface covering a step.

A color filter 230 and a light blocking member 220 are formed on the first interlayer insulating layer 180a.

The light blocking member 220 is formed in a lattice structure having an opening corresponding to an area that displays an image, and is made of a material through which light cannot penetrate. The color filter 230 is formed in the opening of the light blocking member 220. The color filter 230 is disposed to correspond to the image displaying area, that is, a pixel area.

The color filter 230 may display one of primary colors such as three primary colors of red, green, and blue. The color filter 230 is not limited to the three primary colors of red, green, and blue, but may display cyan, magenta, yellow, white-based colors, and the like. The color filter 230 may be made of a material displaying different colors for every adjacent pixel.

A second interlayer insulating layer 180b covering the color filter 230 and the light blocking member 220 is formed on the color filler 230 and the light blocking member 220. The second interlayer insulating layer 180b may include an inorganic insulator such as a silicon nitride (SiNₓ) and a silicon oxide (SiOₓ), or an organic insulator. Unlike those illustrated in the cross-sectional view of FIG. 2, when a step is generated due to a thickness difference between the color filter 230 and the light blocking member 220, the second interlayer insulating layer 180b includes the organic insulator to planarize a surface covering the step.

A contact hole 185 exposing the drain electrode 175 is formed in the color filter 230, the light blocking member 220, and the interlayer insulating layers 180a and 180b.

A pixel electrode 191 is formed on the second interlayer insulating layer 180b. The pixel electrode 191 may be made of a transparent conductive material such as ITO or IZO.

The pixel electrode 191 includes a first pixel electrode 191a and a second pixel electrode 191b, the overall shapes of the first pixel electrode 191a and the second pixel electrode 191b are a first quadrangle and a second quadrangle, and the first quadrangle of the first pixel electrode 191a may be smaller than the second quadrangle of the second pixel electrode 191b.

An area where the first pixel electrode 191a is formed becomes a first subpixel area and an area where the second pixel electrode 191b is formed becomes a second subpixel area.

Referring to FIG. 1, in the present exemplary embodiment, the first pixel electrode 191a and the second pixel electrode 191b are viewed to be separated from each other at a portion overlapped with the storage electrode line 131. However, the first pixel electrode 191a and the second pixel electrode 191b are physically and electrically connected with each other through a connection electrode 91.

The first pixel electrode 191a and the second pixel electrode 191b respectively include cross stems including horizontal stems and vertical stems crossing the horizontal stems. In addition, each of the first and second pixel electrodes 191a and 191b is divided into four subareas by the horizontal stems and the vertical stems, and each subarea includes a plurality of minute branches. Further, in the present exemplary embodiment, an external stem that surrounds the outer side of the pixel electrode 191 may further be included.

The minute branches of the pixel electrode 191 may form an angle of about 40 degrees to 45 degrees with the gate line 121. Minute branches of two neighboring subareas may perpendicularly cross each other. In addition, the width of the minute branch may be gradually increased toward or away from the cross stem or gaps between the respective minute branches may be different from each other.

The first pixel electrode 191a is physically and electrically connected with the drain electrode 175 through the contact hole 185, and receives a data voltage from the data electrode 175. Since the first pixel electrode 191a and the second pixel electrode 191b are connected with each other by the connection electrode 91, the first pixel electrode 191a and the second pixel electrode 191b receive the same voltage.

The description of the thin film transistors Q and the pixel electrode 191 described above is one example, and the structure of the thin film transistors and the design of the pixel electrode may be modified to enhance side visibility.

The inner partition 400 separating the microcavity is formed between the first pixel electrode 191a and the second pixel electrode 191b. Thus, the microcavity of the first pixel electrode 191a and the microcavity of the second pixel electrode 191b are separated from each other rather than being connected with each other.

A lower alignment layer 11 is formed on the pixel electrode 191, and the lower alignment layer 11 may be a vertical alignment layer. The lower alignment layer 11, formed of a liquid crystal alignment material such as polyamic acid, polysiloxane, and polyimide, may include at least one of generally used materials.

An upper alignment layer 21 is provided in a portion opposite to the lower alignment layer 11, and a microcavity 305 is formed between the lower alignment layer 11 and an upper alignment layer 21. A liquid crystal material including liquid crystal molecules 310 are injected to the microcavity 305, and the microcavity 305 includes a liquid crystal injection hole (307a, 307b).

The microcavity 305 is divided by a plurality of liquid injection hole forming areas FP located in a portion overlapping the gate line 121, and is formed in plural along a direction in which the gate line 121 is extended.

In the present exemplary embodiment, an alignment material forming the alignment layers 11 and 21 and the liquid crystal material including the liquid crystal molecules 310 may be injected into the microcavity 305 using a capillary force.

Referring to FIG. 2 to FIG. 4, the plurality of microcavities 305 may respectively correspond to the pixel areas PX which may correspond to areas for displaying an image. In the exemplary embodiment of the present invention, one pixel includes two microcavities 305a and 305b divided by the inner partition 400, and therefore two microcavities correspond to one pixel.

Referring to FIG. 1 and FIG. 2, in the exemplary embodiment of the present invention, the liquid injection hole is formed in each of the first subpixel area and the second subpixel area in one pixel. With respect to two pixels adjacent to each other along a column direction, the liquid crystal injection hole 307a formed in the first subpixel area of one pixel and the liquid crystal injection hole 307b formed in the second subpixel area of the other pixel are separated by the outer partition 410 formed along a direction that is parallel with the gate line 121.

In this case, the liquid crystal injection holes 307a and 307b are formed along a direction in which liquid crystal injection hole forming regions 307FP are extended. In addition, although it is not illustrated, a roof layer 360 may cover a gap between microcavities 305 neighboring each other along a direction in which the gate line 121 is extended.

A common electrode 270 and a lower insulating layer 350 are provided on the upper alignment layer 21. The common electrode 270 receives a common voltage, and generates an electric field with the pixel electrode 191 to which the data voltage is applied to determine a tilting direction of the liquid crystal molecules 310 in the microcavity 305 between two electrodes. The common electrode 270 forms a capacitor with the pixel electrode 191 and thus maintains an applied voltage after the thin film transistor is turned off. The lower insulating layer 350 may be made of a silicon nitride (SiNₓ) or a silicon oxide (SiOₓ).

In the present exemplary embodiment, the common electrode 270 is formed on the microcavity 305, but the common electrode 270 may be provided below the microcavity 305 in another exemplary embodiment, thereby enabling liquid crystal driving according to an in-plane switching mode.

The roof layer 360 is provided on the lower insulating layer 350. The roof layer 360 supports the microcavity 305, which is a space between the pixel electrode 191 and the common electrode 270, to maintain its shape. The roof layer 306 may include a photo-resist or other organic materials.

Referring to FIG. 4, a part of the roof layer 360 may form the inner partition 400 that separates the first subpixel area and the second subpixel area of the pixel electrode.

That is, as shown in FIG. 4, the microcavities 305a and 305b of the first subpixel area and the second subpixel area are separated from each other, and in this case, the common electrode 270, the lower insulating layer 350, and the roof layer 360 may be formed in a groove between the lateral microcavities 305a and 305b. FIG. 4 illustrates that the inner partition 400 is made of a material of the roof layer 360, but the material forming the inner partition 400 can be changed. The inner partition 400 may be made of an alignment layer material.

The inner partition 400 may include a material that is the same as a material forming the alignment layers 11 and 21. In this case, the inner partition 400) is a portion formed when a remaining solid is agglomerated after the alignment layers 11 and 21 are formed.

An upper insulating layer 370 is provided on the roof layer 360. The upper insulating layer 370 may contact the upper surface of the roof layer 360. The upper insulating layer 370 may be made of a silicon nitride (SiNₓ) or a silicon oxide (SiOₓ).

An overcoat 390 is provided on the upper insulating layer 370. In the present exemplary embodiment, the overcoat 390 contacts the upper surface and the side surface of the upper insulating layer 370, and may also contact a side surface of the roof layer 360 exposed to the outside.

The overcoat 390 fills the liquid crystal injection hole formation area 307FP and covers the liquid crystal injection hole 307 of the microcavity 305 exposed by the liquid crystal injection hole formation area 307FP. The overcoat 390 may be formed of a thermosetting resin, silicon oxycarbide, or graphene.

Another overcoat (not shown) formed of an inorganic layer or an organic layer may be provided on the overcoat 390. The overcoat protects the liquid crystal molecules 310 injected to the microcavity 305 from an external impact and planarizes the layer.

A polarizer (not shown) is provided below the insulation substrate 110 and above the upper insulating layer 370. The polarizer may include a polarizing element which generates polarization and a TAC (tri-acetyl-cellulose) layer which secures durability, and in some exemplary embodiments, an upper polarizer and a lower polarizer may have transmissive axes which are perpendicular or parallel to each other.

Referring to FIG. 4, the microcavity 305 corresponding to one pixel area includes a first area X and a second area Y. The first region X and the second region Y are partitioned by the inner partition 400. The inner partition 400 is located along a direction in which the storage electrode line 131 is extended.

The first pixel electrode 191a is located corresponding to the first region X and the second pixel electrode 191b is located corresponding to the second area Y. As previously described, the first pixel electrode 191a and the second pixel electrode 191b are physically and electrically connected by the connection electrode 91.

The first injection hole 307a is formed in the first area X and the second injection hole 307b is formed in the second area Y. The first injection hole 307a and the second liquid crystal injection hole 307b are located opposite to each other with reference to the inner partition 400. In addition, the first injection hole 307a and the second liquid crystal injection hole 307b are located opposite to each other with reference to an imaginary line that crosses the center of one pixel. Referring to FIG. 2, the first injection hole 307a is provided in the lower right end of the pixel and the second injection hole 307b is provided in the top left end of the pixel.

In the present exemplary embodiment, a first liquid crystal molecule 310a is injected to the first area X and a second liquid crystal molecule 310b is injected to the second area Y. The first liquid crystal molecule 310a and the second liquid crystal molecule 310b may have different physical properties. Specifically, the first liquid crystal molecule 310a and the second liquid crystal molecule 310b may have different dielectric constants.

Here, in the present exemplary embodiment, when a voltage is applied to the pixel electrode 191 and the common electrode 270 and thus an electric field is formed in the liquid crystal layer, the first liquid crystal molecule 310a and the second liquid crystal molecule 310b which had been vertically aligned when the electric field is not applied have different tilting angles. Thus, since a luminance value varies while a pixel area part corresponding to the first area X and a pixel area part corresponding to the second area X have different voltage-transmittance curved lines in spite of one pixel area, the visibility may be improved.

In addition, referring to FIG. 2, in one pixel of the display device according to the exemplary embodiment of the present invention, the first injection hole 307a and the second injection hole 307b are formed symmetrical to each other in four directions, and are separated with an injection hole of an adjacent pixel in a column direction by the outer partition 410. Further, referring to FIG. 1, the first injection hole 307a and the second injection hole 307b are connected with an injection hole of an adjacent pixel in a row direction by the outer partition 410.

Thus, in the display device according to the exemplary embodiment of the present invention, different liquid crystals may be injected respectively to the first area X and the second area Y of the pixel. In addition, the first area X to which the first liquid crystal molecule 310a is injected and the second area Y to which the second liquid crystal molecule 310b is injected are alternately located along a column direction of the display device. That is, the same liquid crystals are aligned in microcavities of the same rows along the row direction, and the first area X and the area Y are alternately orderly aligned in microcavities in a column direction of the display device.

That is, an alignment of the first area X, the second area Y, the first area X, and the second area Y is repeated along the column direction of the display device. (X-Y-X-Y-X-Y . . . alignment)

This is because the outer partition 410 where a plurality of teeth formed along a direction parallel with the gate line 121 are formed in the display device according to the exemplary embodiment of the present invention. Such an outer partition 410 separates a first injection hole and a second injection hole of pixels that are adjacent to each other in the column direction, and thus liquid crystals are separated rather than being mixed with each other and fill the respective microcavities 305a and 305b.

However, when the outer partition 410 is not formed in the display device, the first area X and the second area Y are not alternately aligned in the microcavities in the column direction of the display device.

That is, an alignment of the first area X, the second area Y, the second area Y, and the first area X is repeated along the column direction of the display device. (X-Y-Y-X-X-Y-Y-X-X . . . alignment)

Such an effect will be described in detail with reference to the accompanying drawings.

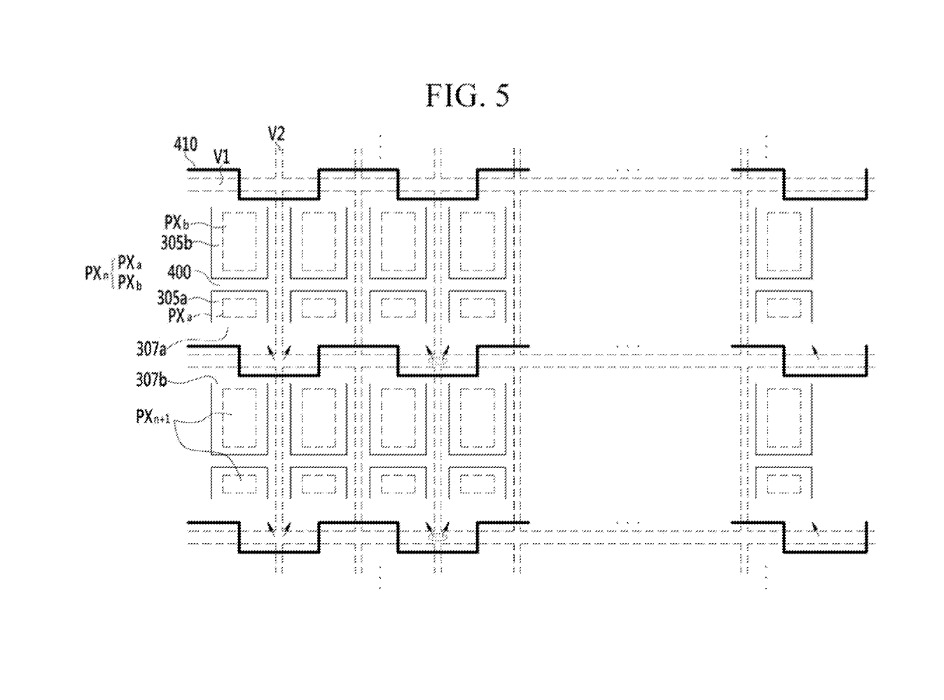

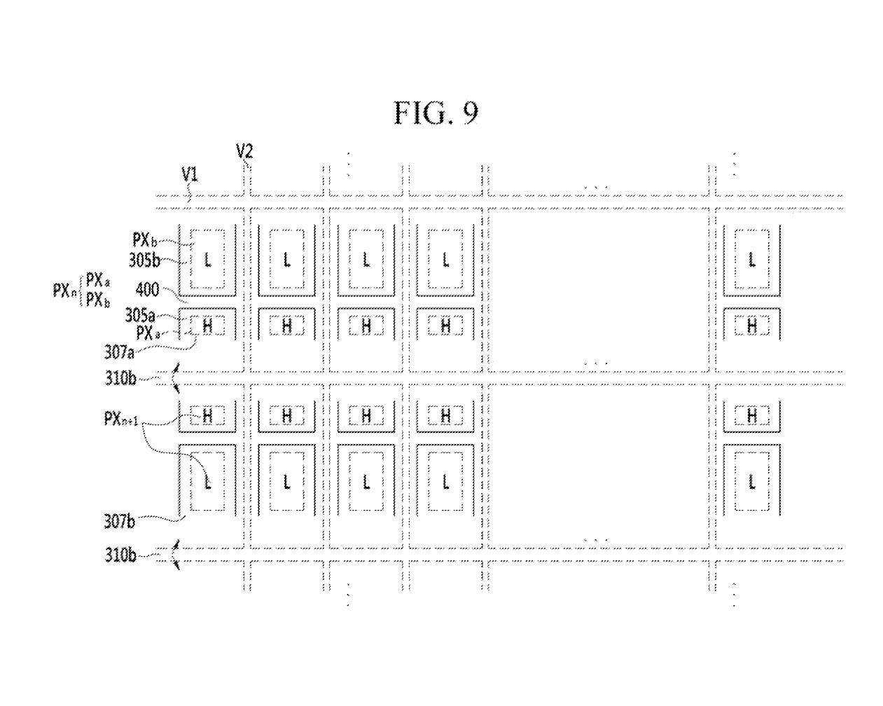

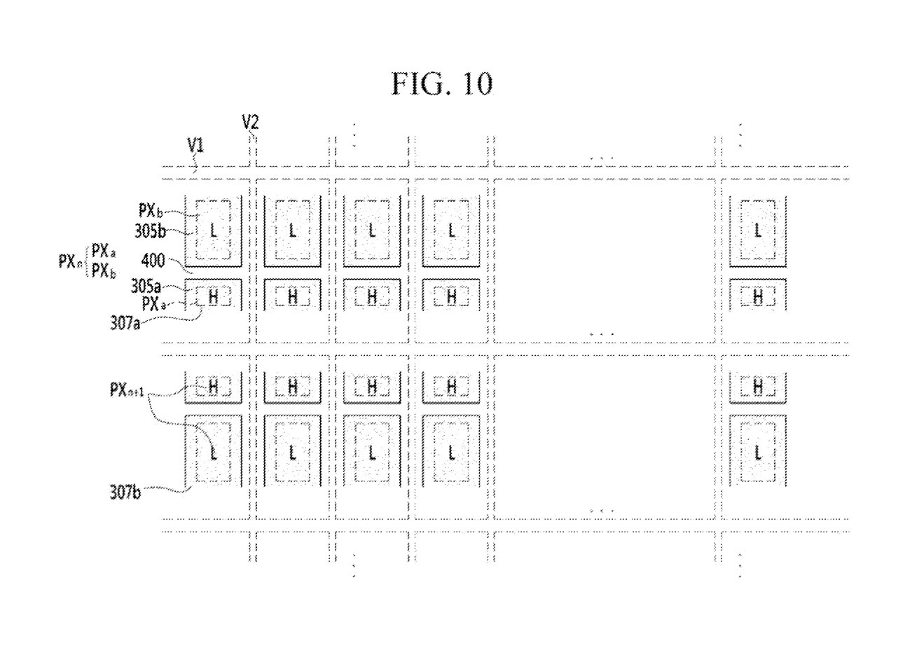

FIG. 5 to FIG. 8 illustrate a liquid crystal injection process of the display device according to the exemplary embodiment of the present invention. FIG. 9 and FIG. 10 illustrate a liquid crystal injection process of a display device according to a comparative example of the present invention.

Referring to FIG. 5, the outer partition 410 is formed between a pixel electrode PXn and a pixel electrode PX(n+1) that are adjacent to each other along the column direction. The outer partition 410 extends along a row direction and has a tooth structure, and each tooth has a structure in which an open-top quadrangular structure and an open-bottom quadrangle structure are repeated.

The open-top quadrangular area (hereinafter referred to as a first quadrangular area) formed by the partition 410 includes a first injection hole 307a exposing the first subpixel area, and the open-bottom quadrangular area (hereinafter referred to as a second quadrangular area) formed by the partition 410 includes a second injection hole 307b exposing the second subpixel area.

That is, the first quadrangular area and the second quadrangular area are alternately provided in the partition 410.

Referring to FIG. 5, the first liquid crystal molecules 310a are dripped to the first quadrangular area of the partition 410. Since the first injection holes 307a of two pixels adjacent to each other along the row direction are formed in the first quadrangular area, the first liquid crystal molecules 310a dripped to the first quadrangular area enter the first microcavity 305a through the first injection hole 307a.

However, since the second injection holes 307b of the pixels are separated by the partition 410, the first liquid crystal molecules 310a do not pass through the second injection hole.

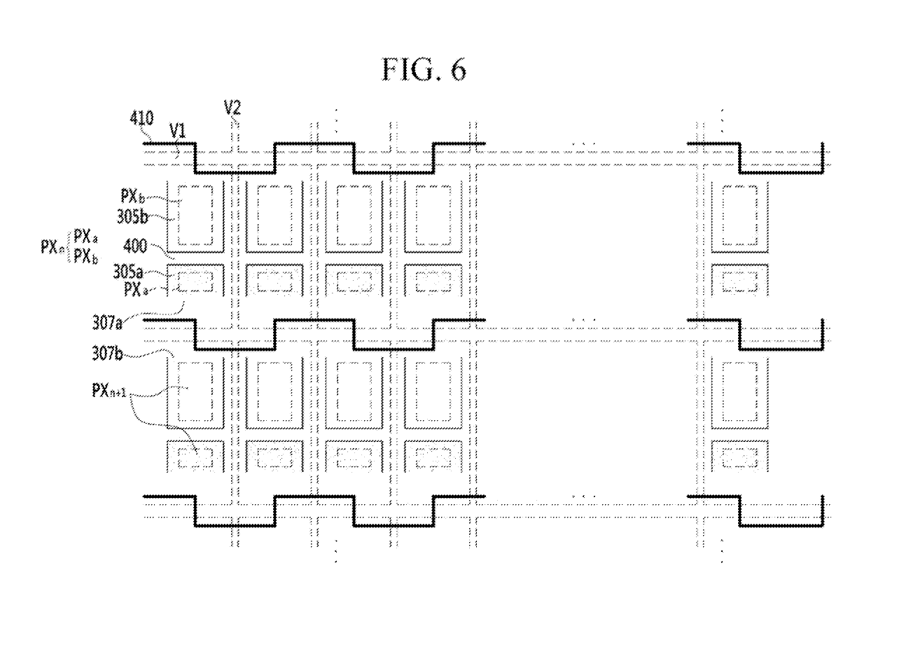

FIG. 6 illustrates a state that the first microcavity 305a is filled with the first liquid crystal molecules 310a through the above-stated process.

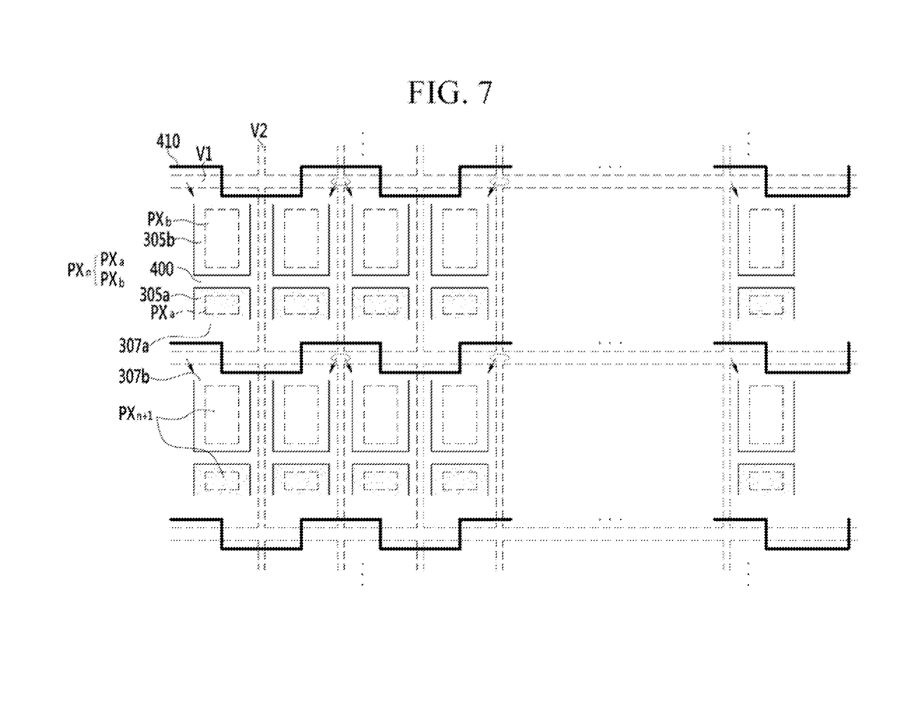

Next, referring to FIG. 7, the second liquid crystal molecules 310b are dripped to the second quadrangular area where the second injection hole 307b is included.

In each area partitioned by the partition 410, an area where the second liquid crystal molecules 310b are dripped is an area where the first liquid crystal molecules 310a are not dripped.

The second quadrangular area includes a second injection hole 307b of each pixel. Thus, the second liquid crystal molecules 310b dripped to the second quadrangular area enter the second microcavity 305b of each pixel through the second injection hole 307b of each pixel.

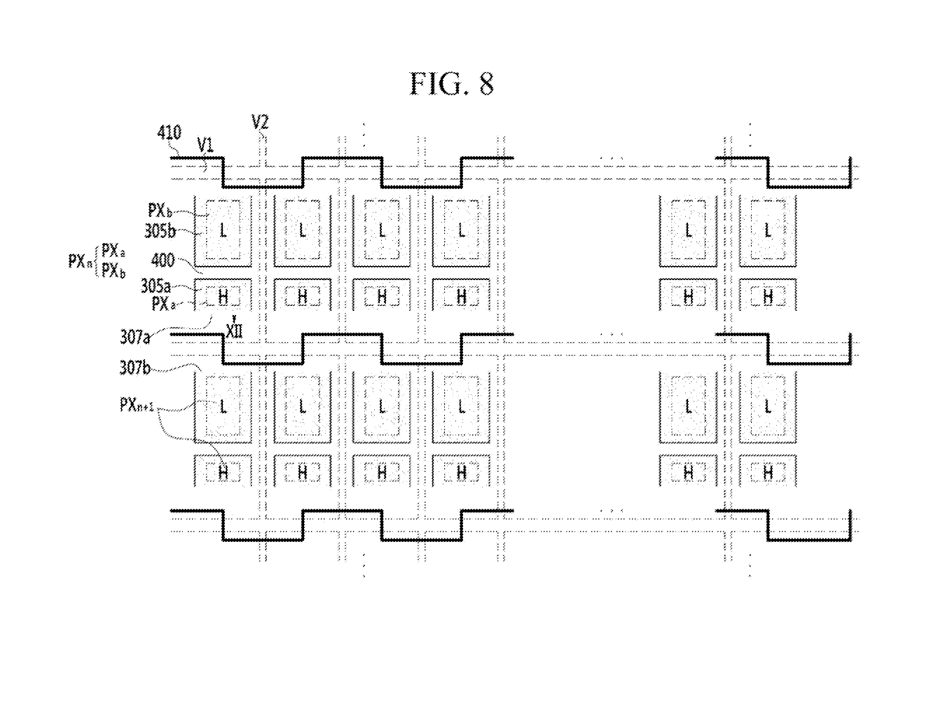

FIG. 8 illustrates a display device in which the first microcavity 305a and the second microcavity 305b are both filled with the liquid crystal molecules. In FIG. 8, the first microcavity filled with the first liquid crystal molecules is denoted as H and the second microcavity filled with the second liquid crystal molecule is denoted as L.

Referring to FIG. 8, only H or L continuously exist along a horizontal direction of the display device, and H and L alternately exist along a vertical direction of the display device.

In general, in a conventional display device, visibility is controlled by differentiating a tilt degree of liquid crystals in a first subpixel area (H of FIG. 8) and a second subpixel area (L in FIG. 8) in one pixel. In this case, in order to differentiate the tilt degree of liquid crystal in the first subpixel area and the second subpixel area, a different voltage is needed to be applied to each area, and accordingly a plurality of transistors are required to generate such a voltage difference.

However, in case of the display device according to the exemplary embodiment of the present invention, as previously described with reference to FIG. 2, visibility can be improved by differentiating a tilt degree of liquid crystal in each pixel area by using a simple structure in which only one transistor is provided. That is, in the display device according to the exemplary embodiment of the present invention, liquid crystals respectively having different dielectric constants are injected to each pixel area of the pixel electrode, and thus visibility can be improved by differentiating a tilt degree of the liquid crystal even though the same voltage is applied to the respective areas. As in the exemplary embodiment of the present invention, when different liquid crystals are injected respectively to the first subpixel area and the second subpixel area, a structure in which a plurality of transistors are formed may be applied to improve visibility.

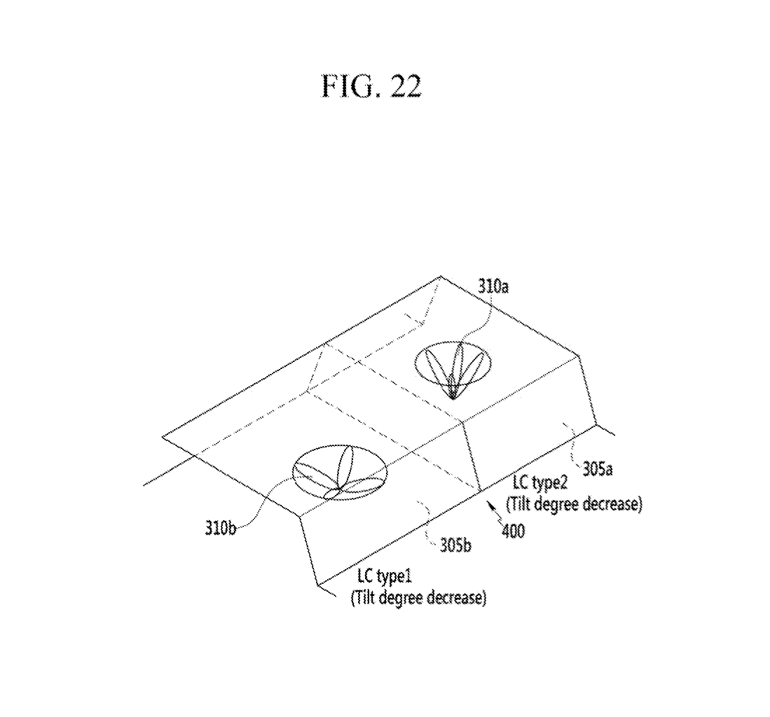

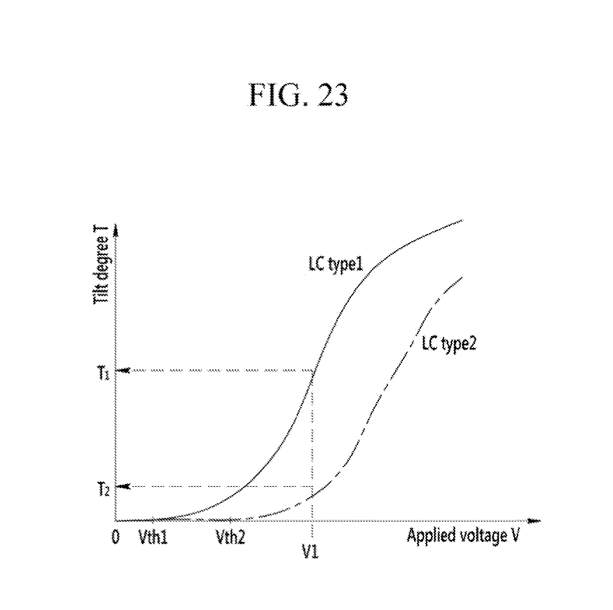

FIG. 22 and FIG. 23 illustrate that a tilt degree of liquid crystal is changed when different liquid crystal molecules are applied to each pixel area.

Referring to FIG. 23, liquid crystal molecules LC type1 and LC type2, each having a different dielectric constant have different tilt degrees T even though the same voltage V1 is applied.

Thus, the liquid crystal molecules are respectively injected to an area where a first microcavity 305a and a second microcavity 305b are divided by the inner partition in one pixel and the same voltage is applied. In this case, as shown in FIG. 22, the tilt degree of the liquid crystal molecules LC type1 and LC type2 are different from each other. Thus, the tail or the body of the liquid crystal molecule can be evenly viewed from a front or a side of the display device, and accordingly visibility can be improved.

In addition, in the display device according to the exemplary embodiment of the present invention, the outer partition 410 that separates the first injection hole and the second injection hole along the first valley V1 is formed, and therefore the area H where the first liquid crystal molecule is formed and the area L where the second liquid crystal molecule is formed are alternately aligned along the column direction. That is, the H area and the L area exist, interposing the first valley V1 therebetween.

However, in the display device according to the comparative example of the present invention, in which no partition is formed along the first valley V1, the area H and the area L cannot be alternately aligned but are repeatedly aligned. That is, for example, the area H exists in both sides of the first valley V1 and the area L exists in both sides of the next valley.

FIG. 9 and FIG. 10 illustrate a liquid crystal injection process of the display device according to the comparative example of the present invention.

Referring to FIG. 9, in the display device of the comparative example of the present invention, in which no partition is formed in the first valley V1, the first subpixel areas may exist in both sides of the first valley V1 or the second subpixel areas exist facing each other, interposing the first valley V1 therebetween.

That is, in a display device having the structure of FIG. 9, liquid crystal molecules injected to each valley are injected through injection holes in both sides of the valley, and therefore areas injected with the same liquid crystal molecules should exist in both sides of the valley.

Thus, the location of the first subpixel area and the location of the second pixel area are continuously switched, interposing the first valley V1 therebetween.

When the second subpixel area PXb is located in a first column, the first subpixel area PXa is located above in a second column, and the second subpixel area PXb is located above again in a third column.

FIG. 10 illustrates the display device to which liquid crystal is injected according to the comparative example of the present invention. Referring to FIG. 10, the area H and the area L cannot be regularly repeated along the column direction of the display device, and thus the area H and the area L aligned twice, respectively.

That is, as previously described, in the display device according to the exemplary embodiment of the present invention, different types of liquid crystal are injected to each of two separated areas in one pixel and alignment of H-L-H-L . . . is regularly repeated along the column direction of the display device.

However, as shown in FIG. 9, in the display device according to the comparative example of the present invention, an alignment of H-L-L-H-H-L . . . is repeated along the column direction of the display device. Such an alignment is generated for injection of different types of liquid crystal to subpixel areas of each pixel in the display device where a partition is not formed in the first valley.

When the pixel direction is inverted in each row, a spot may be viewed when substantial displaying of an image.

However, in the display device according to the exemplary embodiment of the present invention, a partition that separates a first injection hole and a second injection hole is formed in the first valley such that alignment of H-L-H-L . . . is regularly repeated along the column direction of the display, and accordingly a spot can be prevented from being viewed.

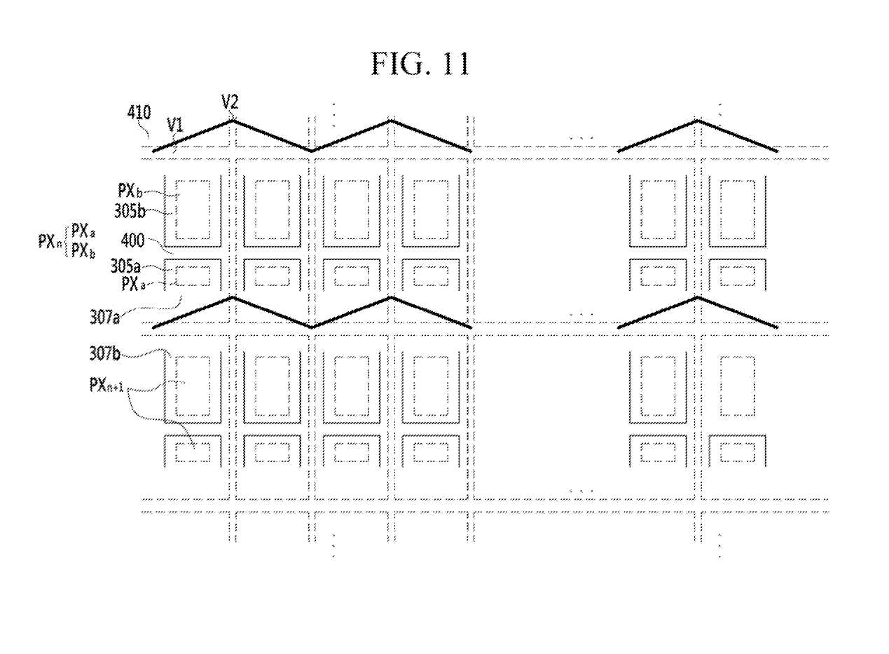

FIG. 11 illustrates a display device according to another exemplary embodiment of the present invention. A display device according to an exemplary embodiment of FIG. 11 is almost the same as the display device according to the exemplary embodiment of FIG. 1. A description for the similar constituent elements will be omitted.

Referring to FIG. 11, a partition 410 is formed in the shape of a triangle rather than a tooth shape of FIG. 1. However, in FIG. 11, one triangle shares the same liquid crystal hole 307a of two pixels that are adjacent to each other, and a first injection hole 307a and a second injection hole 307b are separated by the partition 410 as in the display device of FIG. 1. Thus, the display device having the partition of the structure of FIG. 11 also has the previously stated effect.

That is, in the display device according to the present exemplary embodiment, a different liquid crystal molecule fills each subpixel area of one pixel, thus visibility of the display device can be improved with a simple-structured transistor, and microcavities injected with the respective liquid crystal molecules are alternately regularly aligned in the entire display device so that a spot can be prevented from being viewed.

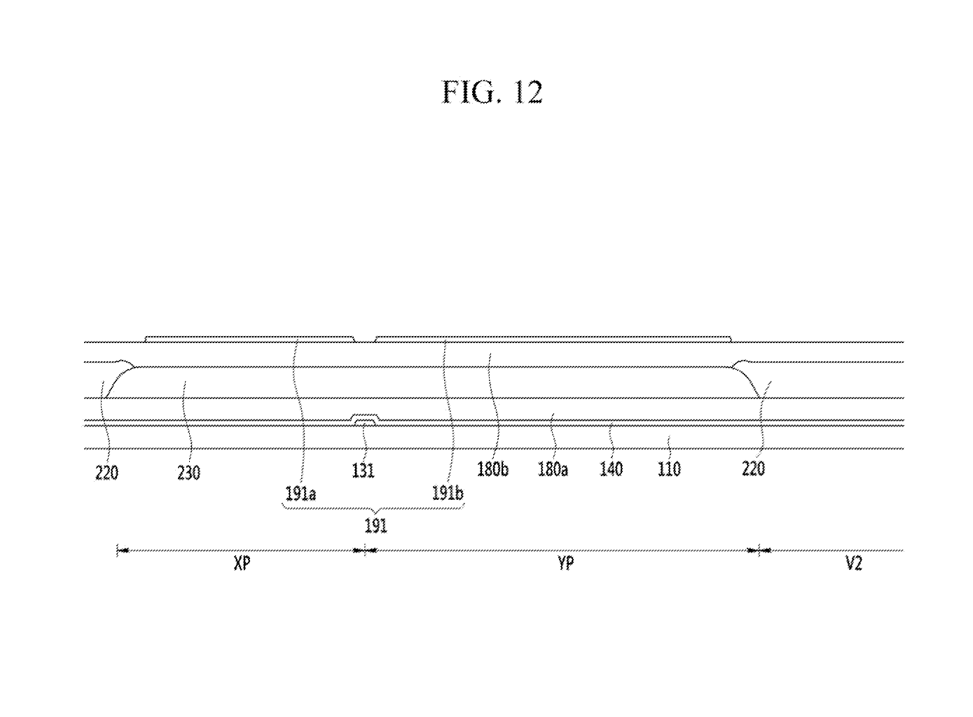

Next, a method for manufacturing a display device according to an exemplary embodiment of the present invention will be described with reference to FIG. 12 to FIG. 20.

FIG. 12 to FIG. 20 are process cross-sectional views of a display device with reference to a cross-sectional view of FIG. 1, taken along the line XII-XII.

Referring to FIG. 12, a storage electrode line 131 is extended in parallel with a thin film transistor, and a gate line is formed on the substrate 110. A first interlayer insulating layer 180a is formed to cover the thin film transistor. The color filter 230 and the light blocking member 220 are formed on the first interlayer insulating layer 180a, and then a second interlayer insulating layer 180b is formed on the color filter 230 and the light blocking member 220. The pixel electrode 191 is formed on the second interlayer insulating layer 180b. The pixel electrode 191 may be formed to include the first pixel electrode 191a corresponding to a first reserve area XP and the second pixel electrode 191b corresponding to a second reserve area YP.

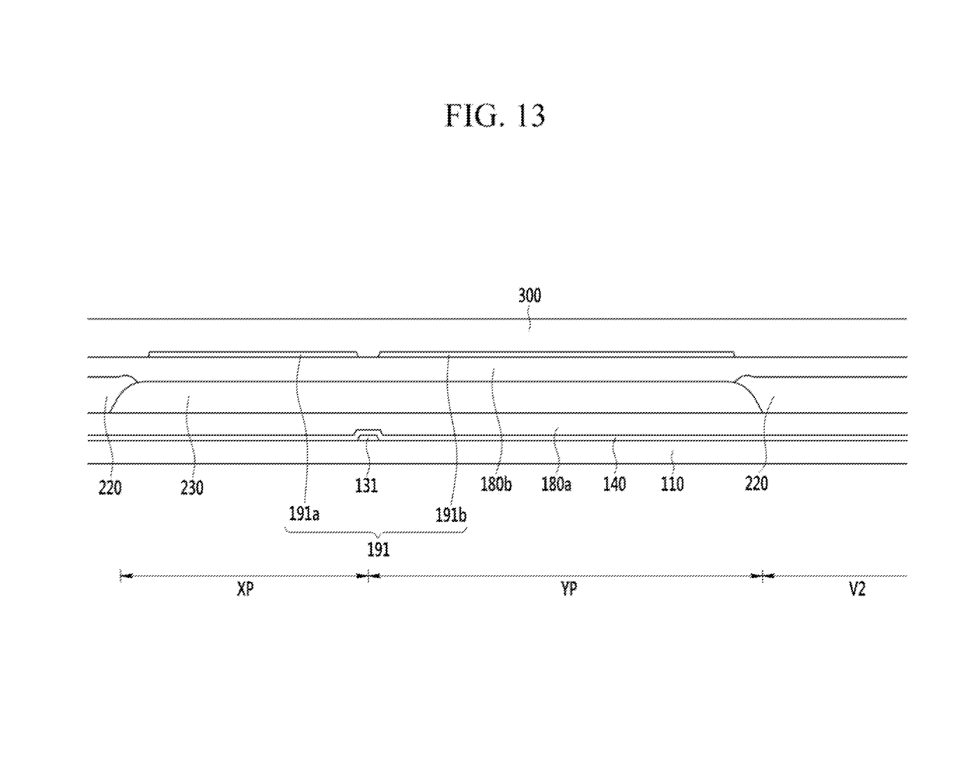

Next, referring to FIG. 13, a sacrificial layer 300 is formed on the pixel electrode 191. In the present exemplary embodiment, the sacrificial layer 300 is formed to cover the first pixel electrode 191a, the second pixel electrode 191b, and a gap between the first pixel electrode 191a and the second pixel electrode 191b in one pixel area.

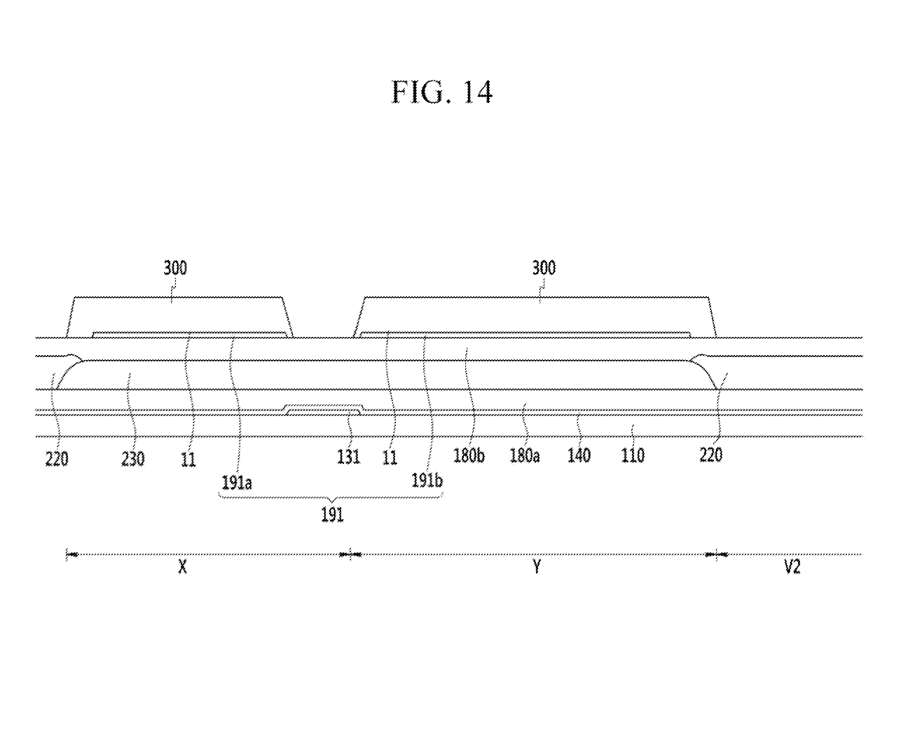

Next, referring to FIG. 14, a recess portion is formed between the first pixel electrode 191a and the second pixel electrode 191b by patterning the sacrificial layer 400. In addition, the sacrificial layer 300 is patterned to be located only in the first pixel areas X and Y. That is, the sacrificial layer 300 exists only above each pixel electrode with reference to one pixel area, and thus an H-shaped groove is formed by patterning the sacrificial layer 300.

That is, in the entire substrate, the sacrificial layer is patterned in a shape in which a plurality of island-shaped quadrangles are formed in a matrix format.

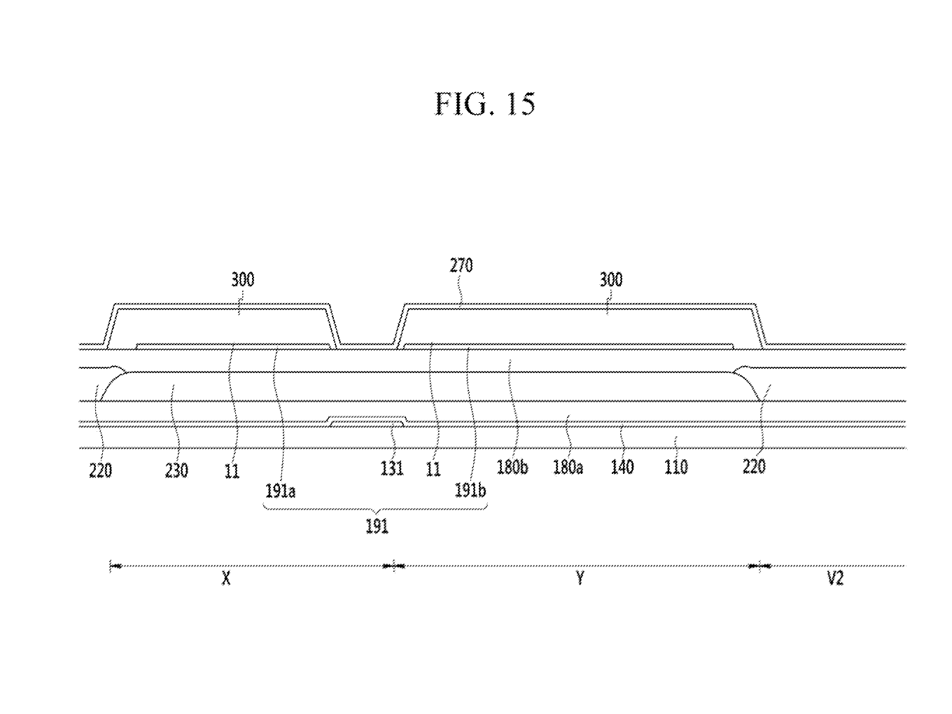

Next, referring to FIG. 15, a common electrode 270 is formed on the sacrificial layer 300). In this case, the common electrode 270 is formed along the patterned sacrificial layer 300, and accordingly the common electrode 270 is formed in the recess portion.

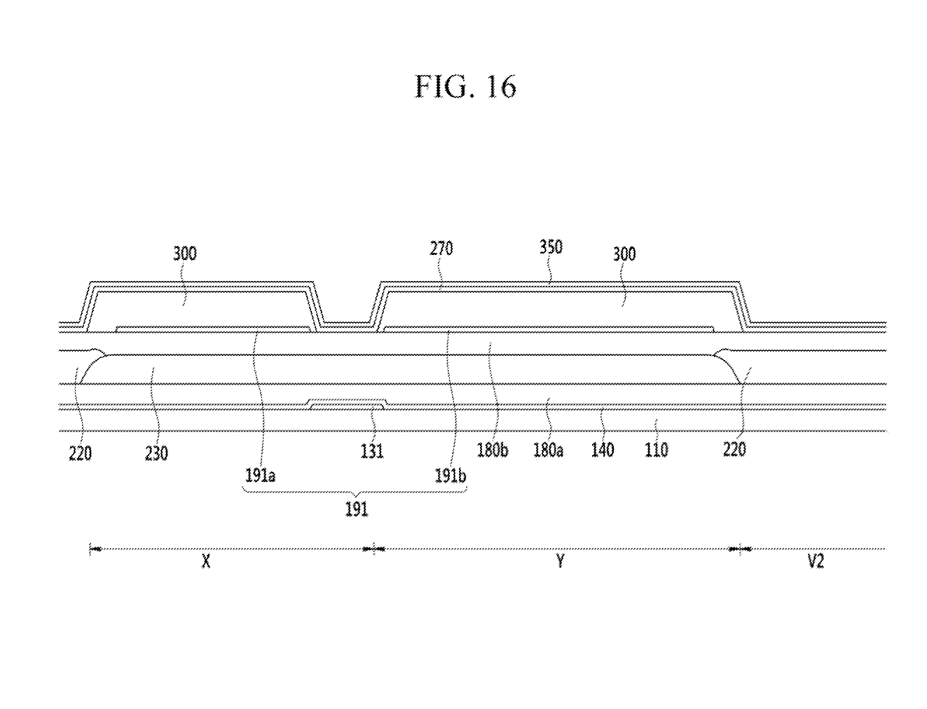

Next, referring to FIG. 16, a lower insulating layer 350 is formed on the common electrode 270. The lower insulation layer 350 may also be formed in the recess portion.

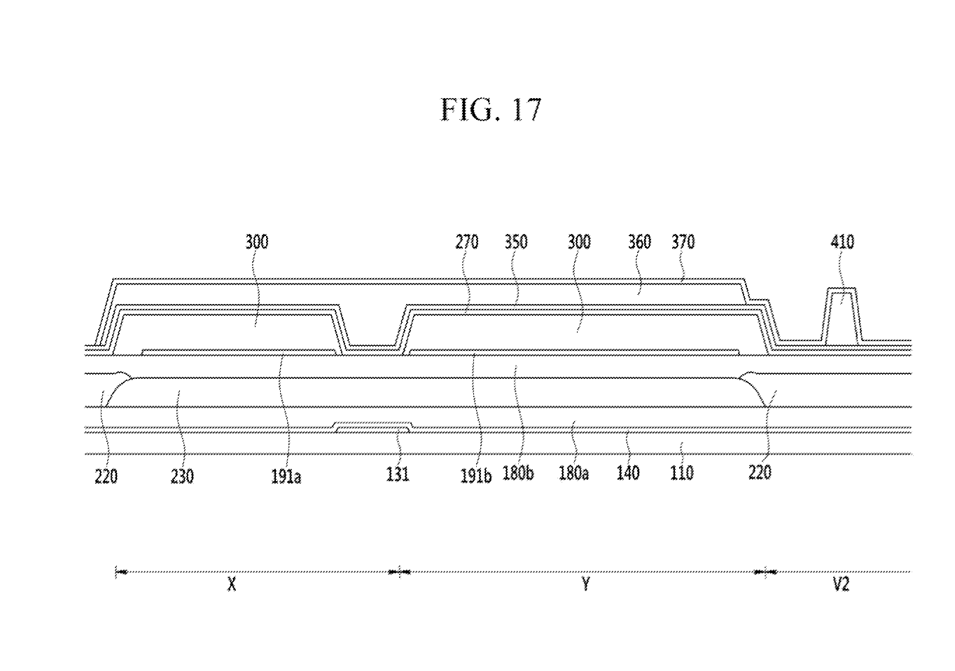

Next, referring to FIG. 17, a roof layer 360 is formed. The roof layer 360 is patterned to be formed only above the sacrificial layer, and serves as an outer partition 410 between the first valleys that have been already removed.

The roof layer 360 is not patterned but is continuously formed along a row direction of the substrate, and thus the second valley existing between neighboring pixels is filled by the roof layer. Such a second valley becomes lateral partitions of the H-shaped inner partition.

In addition, the roof layer 360 is formed to fill a groove formed between two microcavities of one pixel, and therefore the roof layer 360 becomes a horizontal partition of the H-shaped inner partition.

Next, an upper insulating layer 370 is formed on the roof layer 360. The upper insulating layer 370 is formed to surround the side surface of the roof layer 360, and thus protects the roof layer 360 during a sacrificial layer removing process. Likewise, the side surface of the roof layer 360, which serves as the outer partition 410, is protected by the upper insulating layer 370.

Although it is not illustrated in the drawing, the roof layer 360 may be patterned to form the partition 410 as shown in FIG. 1.

Referring to FIG. 17, the roof layer 360 exposes a side surface of the sacrificial layer 300 corresponding to the first pixel electrode 191a, but does not expose a side surface of the sacrificial layer 300 corresponding to the second pixel electrode 191b. That is, the roof layer 360 serves as the partition 410 of FIG. 1, and thus separates a first injection hole to be formed in a first subpixel area and a second injection hole to be formed in a second subpixel area.

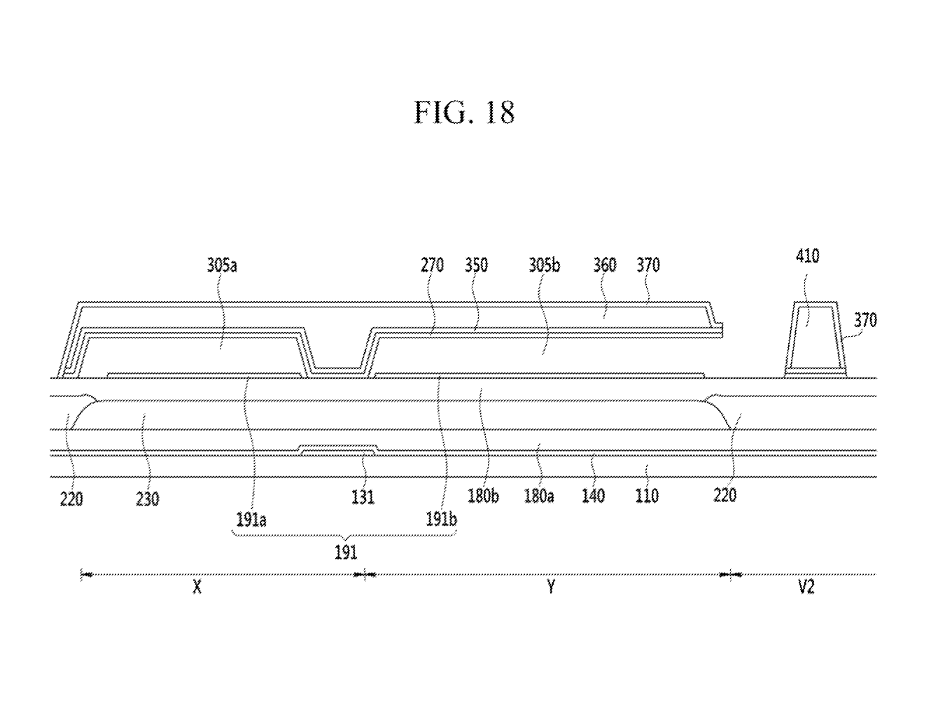

Next, as shown in FIG. 18, an injection hole is formed by removing the common electrode 270 and the lower insulating layer 350.

Next, microcavities 305a and 305b are formed by removing the sacrificial layer 300. Although it is not illustrated in FIG. 18, an area of which one side is blocked by the roof layer and to which a side surface of the sacrificial layer is exposed is formed in an area where the first subpixel electrode 191a is formed. Thus, the sacrificial layer is removed using the exposed side surface of the sacrificial layer and thus sacrificial layers at both sides of one pixel are removed and the microcavities are formed. After the sacrificial layer is removed, as shown in FIG. 18, the first microcavity and the second microcavity are formed, and exposed portions of the side surfaces of the sacrificial layer become the first injection hole and the second injection hole.

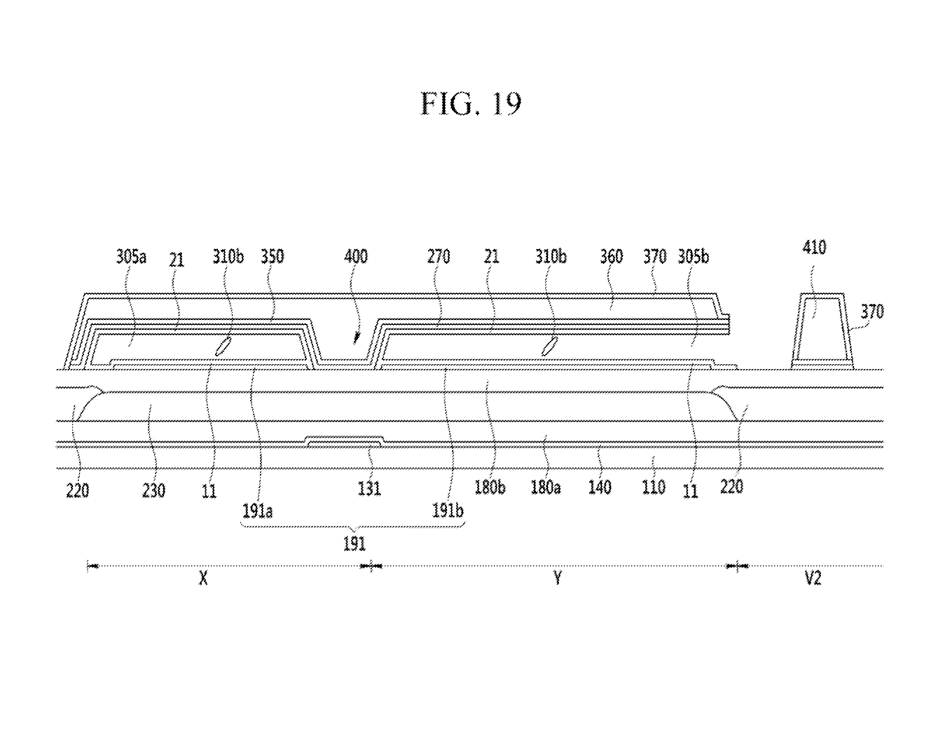

Next, as shown in FIG. 19, a bake process is performed after injecting the aligning material including a solid and a solvent through the first and second injection holes. When a curing process is performed after injection of the aligning material into the microcavities 305a and 305b, a solution component is evaporated and the alignment material remains on a wall surface in the microcavities 305a and 305b.

Thus, a first alignment layer 11 is thrilled on the pixel electrode 191 and a second alignment layer 21 is formed below the common electrode 270. The first alignment layer 11 and the second alignment layer 21 are formed to face each other, interposing the microcavities 305a and 305b therebetween, and edges of the pixel area are connected with each other.

In this case, the first and second alignment layers 11 and 21 may be aligned in a direction that is perpendicular to the substrate 110, excluding side surfaces of the microcavities 305a and 305b. Additionally, a process for irradiating UV rays to the first and second alignment layers 11 and 21 is performed such that the alignment layers 11 and 21 may be aligned, in parallel with the substrate 110.

Next, different liquid crystals are injected respectively through the first injection hole and the second injection hole. The liquid crystal injection process is the same as the process described with reference to FIG. 5 to FIG. 8, and therefore no further description will be provided.

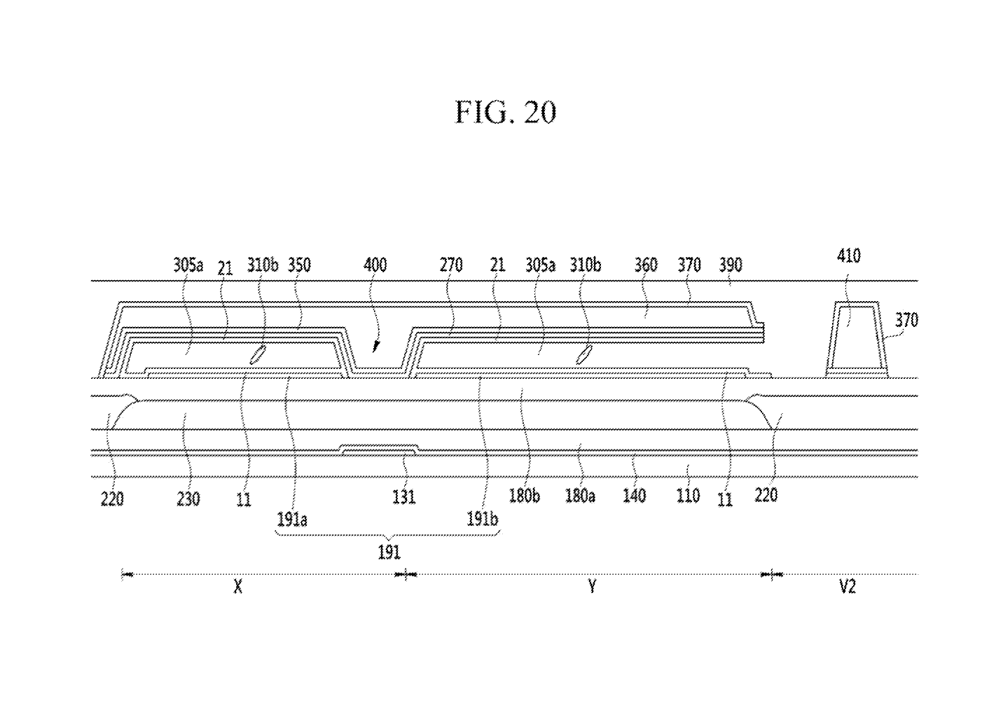

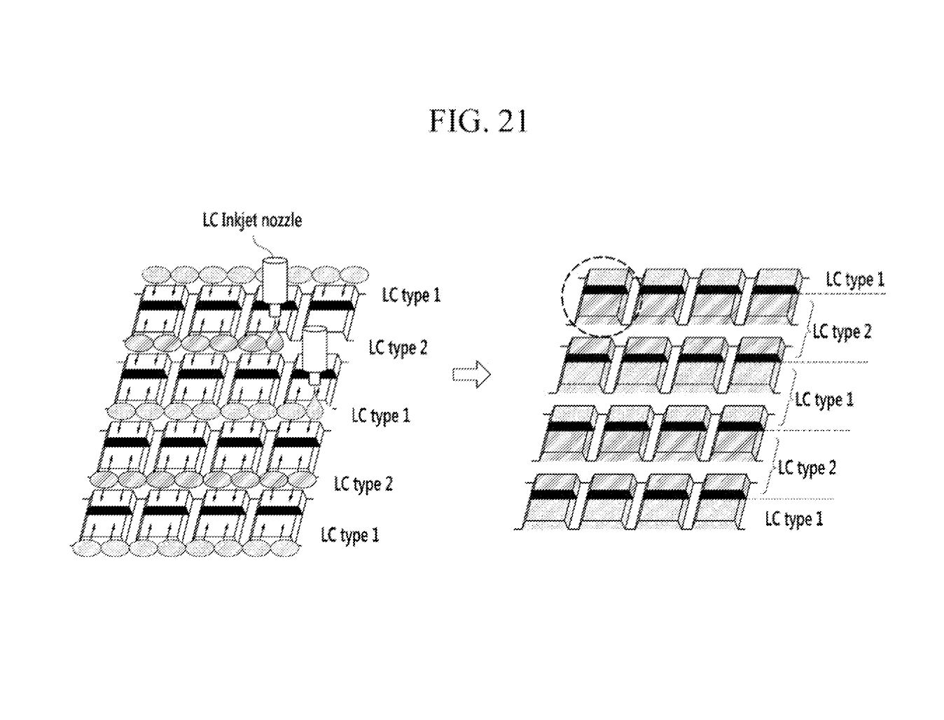

Next, as shown in FIG. 20, an overcoat 390 is formed on the upper insulating layer 370 to cover the first and second injection holes. Through such a process, the display device according to the exemplary embodiment of the present invention is manufactured.

While this invention has been described in connection with what is presently considered to be practical exemplary embodiments, it is to be understood that the invention is not limited to the disclosed embodiments, hut, on the contrary, is intended to cover various modifications and equivalent arrangements included within the spirit and scope of the appended claims.

<Description of symbols>

| | |
|---|---|
| 110: substrate | 191: pixel electrode |
| 270: common electrode | 121: gate line |
| 171: data line | 173: source electrode |
| 175: drain electrode | 154: semiconductor |
| 300: sacrificial layer | 310: liquid crystal molecule |
| 305: microcavity | 307: liquid crystal injection hole |
| 350: lower insulating layer | 360: roof layer |
| 370: upper insulating layer | 390: overcoat |
| 400: inner partition | 410: outer partition |

What is claimed is:

1. A display device comprising:
a substrate;
a thin film transistor provided on the substrate;
a pixel electrode connected with one terminal of the thin film transistor;
a roof layer provided facing the pixel electrode;
a liquid crystal layer formed between the pixel electrode and the roof layer and including a first liquid crystal layer having a first liquid crystal injection hole and to which a first liquid crystal molecule is injected and a second liquid crystal layer having a second liquid crystal injection hole and to which a second liquid crystal molecule is injected;
an H-shaped inner partition separating the first liquid crystal layer and the second liquid crystal layer; and
an outer partition formed in a liquid injection hole forming area of the substrate,
wherein the liquid crystal layer is arranged in plural in a matrix format in the substrate,
the outer partition is formed along a row direction between the plurality of liquid crystal layers, and
the outer partition separates a first liquid crystal injection hole and a second liquid crystal injection hole of two liquid crystal layers that are adjacent to each other along a column direction.

2. The display device of claim 1, wherein the first liquid crystal layer and the second crystal layer form one pixel corresponding to one pixel electrode and display different grays,
a first valley and a second valley are formed along a row direction of a plurality of pixels of the display device, and
with respect to two pixels facing each other, interposing the first valley therebetween, a first area of a liquid crystal layer of one pixel faces a second area of a liquid crystal layer of the other pixel.

3. The display device of claim 2, wherein areas alternately formed and alternately partitioned in a row direction along the plurality of liquid crystal layers of the outer partition respectively comprise only first liquid crystal injection holes or only second liquid crystal injection holes of two pixels adjacent along a row direction, and
the first liquid crystal injection hole and the second liquid crystal injection hole do not exist together in each area partitioned by the outer partition.

4. The display device of claim 1, wherein only a first area or a second area exists in a row direction of the plurality of liquid crystal layers of the display device, and
the first area and the second area are alternately disposed along a column direction of the plurality of liquid crystal layers of the display device.

5. The display device of claim 1, wherein when an electric field is applied to the liquid crystal layer, a tilt degree of liquid crystal molecules in the first area and a tilt degree of liquid crystal molecules in the second area are different from each other.

6. The display device of claim 5, wherein the liquid crystal molecules respectively injected to the first area and the second area have different dielectric constants.

7. The display device of claim 1, wherein the pixel electrode comprises a first pixel electrode and a second pixel electrode respectively located in the first area and the second area, and the first pixel electrode and the second pixel electrode are connected with each other.

8. The display device of claim 1, wherein the inner partition and the outer partition are made of the same material as the roof layer, and
the inner partition and the outer partition are connected with the roof layer.

9. The display device of claim 1, wherein a first injection hole existing in the first area and a second injection hole existing in the second area of the liquid crystal layer are disposed opposite to each other with reference to an imaginary line that crosses the center of the liquid crystal layer.

10. The display device of claim 1, wherein an area of the outer partition, repeated alternately, is formed in the shape of a quadrangle of which one side is removed.

11. The display device of claim 1, wherein an area of the outer partition, repeated alternately, is formed in the shape of a triangle of which one side is removed.

12. A method for manufacturing a display device, comprising:
forming a thin film transistor on a substrate;
forming a pixel electrode to be connected with one terminal of the thin film transistor;
patterning a sacrificial layer on the pixel electrode to form grooves in the sacrificial layer;
forming an outer partition by coating a roof layer on the sacrificial layer and patterning the roof layer;
forming a first microcavity where the first liquid crystal injection hole is formed and a second microcavity where the second liquid crystal injection hole is formed by removing the sacrificial layer; and
injecting a first liquid crystal material to the first microcavity and injecting a second liquid crystal material to the second microcavity,
wherein when coating the roof layer on the sacrificial layer and forming the outer partition,
the partition is formed along a row direction between a plurality of pixels formed on a substrate, and
the outer partition separates a first liquid crystal injection hole and a second liquid crystal injection hole of two liquid crystal layers that are adjacent to each other in a column direction.

13. The method for manufacturing the display device of claim 12, wherein, when coating the roof layer on the sacrificial layer and forming the outer partition, an inner partition is formed while the roof layer is filled in the grooves formed by patterning the sacrificial layer.

14. The method for manufacturing the display device of claim 12, wherein a first area and a second area of the liquid crystal layer form one pixel corresponding to one pixel electrode,
the outer wall is alternately formed in a row direction along a plurality of liquid crystal layers,
each of areas alternately partitioned by the outer partition comprise only first liquid crystal injection holes or only second liquid crystal injection holes of two pixels adjacent to each other in a row direction, and
the liquid crystal injection hole and the second liquid crystal injection hole do not exist together in each area partition by the outer partition.

15. The method for manufacturing the display device of claim 12, wherein the inner partition and the outer partition are made of the same material as the roof layer, and
when the roof layer is coated and patterned, the inner partition and the outer partition are simultaneously formed such that the roof layer, the inner partition, and the outer partition are connected all in one.

16. The method for manufacturing the display device of claim 12, wherein a tilt degree of a liquid crystal molecule included in the first liquid crystal material in the first area and a tilt degree of a liquid crystal molecule included in the second liquid crystal material in the second area are different from each other.

17. The method for manufacturing the display device of claim 12, wherein the liquid crystal molecules respectively injected to the first area and the second area have different dielectric constants.

18. The method for manufacturing the display device of claim 14, wherein a plurality of pixels arranged in a matrix format are formed on a substrate of the display device,
only the first area or only the second area exists along a row direction of the plurality of pixels, and
the first area and the second area are alternately arranged along a column direction of the plurality of pixels of the display device.

19. The method for manufacturing the display device of claim 12, wherein an area of the outer partition, repeated alternately, is formed in the shape of a quadrangle of which one side is removed.

20. The method for manufacturing the display device of claim 12, wherein an area of the outer partition, repeated alternately, is formed in the shape of a triangle of which one side is removed.
